(19) United States
(12) Patent Application Publication
(10) Pub. No.: US 2015/0228867 A1
(43) Pub. Date: Aug. 13, 2015

(54) LIGHT EMITTING DIODE PACKAGE AND LIGHT EMITTING DEVICE USING THE SAME

(71) Applicant: SAMSUNG ELECTRONICS CO., LTD., Suwon-si (KR)

(72) Inventors: Jung Jin KIM, Hwaseong-si (KR); Yong Min KWON, Seoul (KR); Min Young SON, Seoul (KR); Sung Kyong OH, Suwon-si (KR)

(21) Appl. No.: 14/542,159

(22) Filed: Nov. 14, 2014

(30) Foreign Application Priority Data
Feb. 13, 2014 (KR) 10-2014-0016713

(51) Int. Cl. H01L 33/50; H01L 33/54; H01L 33/56; F21V 29/70

(52) U.S. Cl. CPC H01L 33/505; F21V 29/70; H01L 33/54; H01L 33/56

(57) ABSTRACT

A light emitting diode package includes a package body having first and second electrode structures, a light emitting diode chip having a surface, on which first and second electrodes are disposed. The light emitting diode chip is disposed on the first and second electrode structures of the package body. A sheet-type wavelength conversion layer having a substantially constant thickness is disposed on an upper surface of the light emitting diode chip, and an encapsulating portion is disposed to surround the light emitting diode chip and the wavelength conversion layer. The encapsulating portion has an upper surface substantially parallel to the wavelength conversion layer. Side surfaces of the encapsulating portion have a plurality of side slope sections inclined toward the upper surface of the encapsulating portion.

### CROSS-REFERENCE TO RELATED APPLICATION

This application claims benefit of priority to Korean Patent Application No. 10-2014-0016713 filed on Feb. 13, 2014, with the Korean Intellectual Property Office, the entire content of which is incorporated herein by reference.

### TECHNICAL FIELD

The present disclosure relates to a light emitting diode and a light emitting device using the same.

### BACKGROUND

Light emitting diodes are devices in which a material emits light through the application of electric energy thereto, and in which energy generated by the recombination of electrons and holes in a junction semiconductor is converted to light to be emitted. Such light emitting diodes are widely used as illumination apparatuses, display devices, and light sources, and thus, the development thereof is being accelerated.

In particular, recently, as mobile phone keypads, turn signal lamps, camera flashlights, and the like, using gallium nitride (GaN)-based light emitting diodes, are commercialized, general illumination apparatuses using such light emitting diodes are being actively developed. Since the applications of light emitting diodes are gradually moving to larger, high-powered, and high-efficiency products, such as the backlight units of large televisions (TVs), vehicle headlights, and general illumination apparatuses, there is a need to develop methods of improving color quality and increasing amounts of light emitted from light emitting diodes used in these applications.

### SUMMARY

An aspect of the present disclosure may provide a light emitting diode package having improved color quality and an increased light emission amount.

The technical objectives of the inventive concept are not limited to the present disclosure and other objectives may become apparent to those of ordinary skill in the art based on the following descriptions.

An aspect of the present disclosure relates to a light emitting diode package including a package body including first and second electrode structures, a light emitting diode chip including a surface on which first and second electrodes are disposed. The light emitting diode is disposed on the first and second electrode structures of the package body. A sheet-type wavelength conversion layer having a substantially constant thickness is disposed on an upper surface of the light emitting diode chip. An encapsulating portion is disposed to surround the light emitting diode chip and the wavelength conversion layer.

The encapsulating portion has an upper surface substantially parallel to the wavelength conversion layer. Side surfaces of the encapsulating portion have a plurality of side slope sections inclined toward the upper surface of the encapsulating portion.

The plurality of side slope sections may extend from edges of an upper surface of the package body toward the upper surface of the encapsulating portion at an angle.

The plurality of side slope sections may extend from edges of the upper surface of the package body at an identical angle.

The plurality of side slope sections may include flat surfaces.

Each of the plurality of side slope sections may extend from a flat portion coplanar with a side surface of the package body.

The flat portion may have a thickness of at least 100 μm.

A height of the plurality of side slope sections may be greater than or equal to 50% of a height of the flat portion in a direction perpendicular to an upper surface of the package body.

The plurality of side slope sections may correspond to edges of the upper surface of the light emitting diode chip.

The plurality of side slope sections may have an angle of about 60° to 70° with respect to the upper surface of the package body.

The encapsulating portion may include a material selected from the group consisting of silicone, a modified silicone, epoxy, urethane, oxetane, acrylic, polycarbonate, polyimide, and a combination thereof.

The wavelength conversion layer may be a mixture of a half-cured material and a fluorescent material.

The fluorescent material may include at least a red fluorescent material.

The package body may include a flat surface.

The first and second electrode structures may include first and second through electrodes passing through the package body.

Another aspect of the present disclosure encompasses a light emitting apparatus including a mounting board, and a light emitting diode package disposed on the mounting board and emitting light when power is applied. The light emitting diode package includes a package body including first and second electrode structures, and a light emitting diode chip including a surface on which first and second electrodes are disposed. The light emitting diode chip is disposed on the first and second electrode structures of the package body. A sheet-type wavelength conversion layer having a substantially constant thickness is disposed on an upper surface of the light emitting diode chip, and an encapsulating portion is disposed to surround the light emitting diode chip and the wavelength conversion layer. The encapsulating portion has an upper surface substantially parallel to the wavelength conversion layer, and a side surface inclined toward the upper surface of the encapsulating portion.

Still another aspect of the present disclosure relates to a backlight unit including a substrate and a light source. The light source includes the above-noted light emitting diode package and is disposed on the substrate and configured to emit light from a top surface of the light source or from a side surface of the light source.

Still another aspect of the present disclosure encompasses an illumination apparatus including a light emitting module and a driving unit and a heat dissipation plate. The light emitting module includes a light emitting diode package and a circuit board with the light emitting diode package disposed thereon. The driving unit is configured to drive the light emitting module. The heat dissipation plate is disposed in direct contact with the light emitting module.

Still another aspect of the present disclosure relates to a light emitting diode package including a package body, alight emitting diode chip, a wavelength conversion layer, and an encapsulating portion. The package body includes first and second electrode structures. The light emitting diode chip is disposed on the first and second electrode structures of the package body. The wavelength conversion layer is disposed on an upper surface of the light emitting diode chip. The encapsulating portion is disposed to surround the light emitting diode chip and the wavelength conversion layer. The encapsulating portion has an upper surface parallel to the wavelength conversion layer. Side surfaces of the encapsulating portion have a flat surface coplanar with a side surface of package body. A plurality of side slope sections extend from the flat surface and are inclined toward the upper surface of the encapsulating portion. The plurality of side slope sections have a height greater than or equal to a first height in a direction perpendicular to an upper surface of the package body such that when light emitted from the light emitting diode chip is total internally reflected from the flat surface to an inside of the encapsulating portion, the total internally reflected light is not refracted to be emitted through the upper surface of the encapsulating portion to an outside of the encapsulating portion.

The plurality of side slope sections may have a height greater than or equal to a second height such that the second height is greater than the first height, and light emitted from the light emitting diode chip is not total internally reflected from the flat surface to the inside of the encapsulating portion.

The plurality of side slope sections may have a height greater than or equal to a third height such that the third height is greater than the second height, and light emitted from the light emitting diode chip is total internally reflected and not emitted through the flat surface to the outside of the encapsulating portion.

### BRIEF DESCRIPTION OF DRAWINGS

The above and other aspects, features and other advantages of the present disclosure will be more clearly understood from the following detailed description taken in conjunction with the accompanying drawings, in which like reference characters refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is a perspective view of a light emitting diode package according to an exemplary embodiment of the present inventive concept.

FIG. 2 is a cross-sectional view taken along line A-A′ of the light emitting diode package of FIG. 1.

FIG. 3 is a plan view of the light emitting diode package of FIG. 1.

FIG. 4 is a perspective view of a light emitting diode package according to an exemplary embodiment of the present inventive concept.

FIG. 5A is a perspective view of a light emitting diode package according to an exemplary embodiment of the present inventive concept.

FIG. 5B is a plan view of the light emitting diode package of FIG. 5A.

FIGS. 6 to 10 are diagrams illustrating main processes of a method of fabricating the light emitting diode package of FIG. 1.

FIG. 11 is a diagram illustrating a path of light of a comparative example.

FIG. 12 is a diagram illustrating a distribution of light of a comparative example.

FIG. 13 is a diagram illustrating the change in a light emission amount according to the angle of a side slope section.

FIG. 14 is a diagram illustrating the change of the light emission amount, measured on a light irradiation surface, according to the angle of a side slope section.

FIGS. 15A to 15E are diagrams illustrating a distribution of the line L₂ of FIG. 14 according to the angle of a side slope section.

FIGS. 16 and 17 are diagrams illustrating the change of the light emission amount according to the angle of a side slope section.

FIG. 18 is a cross-sectional view schematically illustrating a backlight including the light emitting diode package of FIG. 1.

FIG. 19 is a cross-sectional view schematically illustrating another backlight including the light emitting diode package of FIG. 1.

FIG. 20 is an example of an illumination apparatus including a light emitting diode package according to an exemplary embodiment of the present inventive concept.

FIG. 21 illustrates a headlamp including a light emitting diode package according to an exemplary embodiment of the present inventive concept.

### DETAILED DESCRIPTION

Hereinafter, embodiments of the present inventive concept will be described in detail with reference to the accompanying drawings. The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

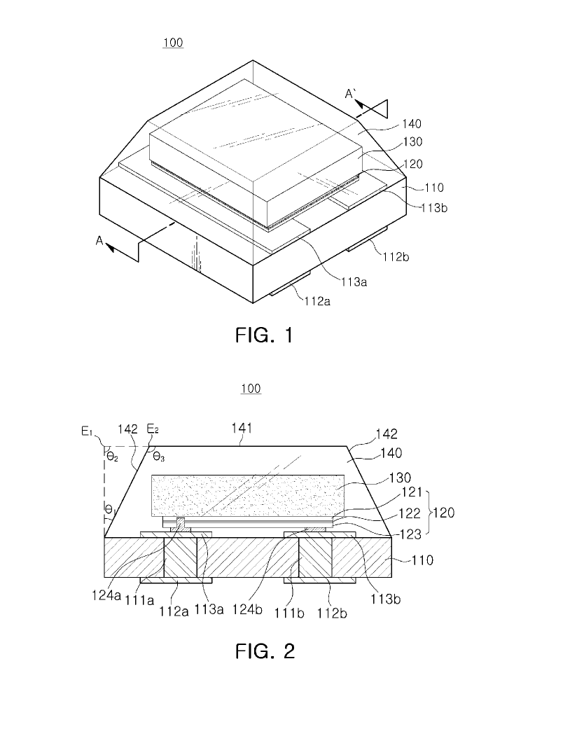

FIG. 1 is a perspective view of a light emitting diode package according to a first exemplary embodiment of the present inventive concept, and FIG. 2 is a cross-sectional view taken along line A-A′ of the light emitting diode package of FIG. 1.

Referring to FIGS. 1 and 2, a light emitting diode package 100 according to the first exemplary embodiment of the present inventive concept may include a package body 110 having first and second electrode structures 113a and 113b, alight emitting diode chip 120 mounted on the package body 110, a wavelength conversion layer 130 disposed on an upper surface of the light emitting diode chip 120, and an encapsulating portion 140 disposed to surround the light emitting diode chip 120 and the wavelength conversion layer 130.

First and second electrode structures 113a and 113b may be formed on the package body 110, and the light emitting diode chip 120 may be mounted on the first and second electrode structures 113a and 113b. First and second electrodes 124a and 124b of the light emitting diode chip 120 may be electrically connected to the first and second electrode structures 113a and 113b by a conductive adhesive such as a solder bump.

More specifically, first and second through electrodes 111a and 111b may penetrate the package body 110 in a thickness direction and pass through one surface on which the light emitting diode chip 120 is mounted and another surface of the package body 110. The first and second electrode structures 113a and 113b may be formed on one surface on which first ends of the first and second through electrodes 111a and 111b are exposed, and the first and second lower electrodes 112a and 112b may be formed on another surface on which the other ends of the first and second through electrodes 111a and 111b are exposed, so that both surfaces of the package body 110 are connected to each other. The package body 110 may be a substrate for fabricating a so called a wafer level package (WLP), that is, a configuration for completing a package in a wafer state.

Here, the package body 110 may be formed of an organic resin containing epoxy, triazine, silicone, polyimide, or the like, or other organic resin materials. Otherwise, in order to improve heat dissipation properties and luminous efficiency, the package body 110 may be formed of a ceramic material, such as Al₂O₃ and AlN, having high heat resistance, excellent heat conductivity, high reflection efficiency, and the like. However, materials of the package body 110 are not limited thereto, and various materials of package body 110 may be used in consideration of heat dissipation properties and electrical connection relations of the light emitting diode package 100.

Further, besides the above-described ceramic substrate, a printed circuit board, a lead frame, or the like may be used as the package body 110 of an exemplary embodiment of the present inventive concept.

The light emitting diode chip 120 may be mounted on the package body 110, and may include a first conductivity type semiconductor layer 121, an active layer 122, and a second conductivity type semiconductor layer which are sequentially arranged. Each of the first and second conductivity type semiconductor layers 121 and 123 may be an n-type or p-type semiconductor layer, and may be formed of a nitride semiconductor material. Therefore, according to an exemplary embodiment of the present inventive concept, the first and second conductivity type semiconductor layers 121 and 123 may respectively refer to, but are not limited to, the n-type and p-type semiconductor layers. The first and second conductivity type semiconductor layers 121 and 123 may have a formula of AlₓIn_{y}Ga_{(1-x-y)}N (where, 0≦x<1, 0≦y<1, and 0≦x+y<1), and may be, for example, GaN, AlGaN, InGaN, and the like.

The active layer 122 may be a layer for emitting visible light (e.g., light having a wavelength range of about 350 nm to 680 nm). The active layer 122 may be configured as an undoped nitride semiconductor layer having a single quantum well structure or a multiple quantum well (MQW) structure. The active layer 122 may be formed to have the MQW structure in which a quantum barrier layer and a quantum well layer of, for example, AlₓIn_{y}Ga_{(1-x-y)}N (where, 0≦x<1, 0≦y<1, and 0≦x+y<1) are alternately stacked to have a predetermined band gap. Electrons and holes are recombined in the MQW structure to emit light. When the active layer 122 has the MQW structure, an InGaN/GaN structure, for example, may be used. The first and second conductivity type semiconductor layers 121 and 123 and the active layer 122 may be formed using a crystal growth process, such as metal organic chemical vapor deposition (MOCVD), molecular beam epitaxy (MBE), and hydride vapor phase epitaxy (HVPE).

A flip-chip structured light emitting diode chip in which first and second electrodes 124a and 124b are arranged on the same side of the light emitting diode chip 120, and a buffer layer may be further included to reduce crystal defects in a semiconductor layer growth process.

The first and second electrodes 124a and 124b may respectively be for applying power to the first and second conductivity type semiconductor layers 121 and 123, and may respectively form ohmic contacts with the first and second conductivity type semiconductor layers 121 and 123.

The first and second electrodes 124a and 124b may be formed of single- or multi-layered conductive materials respectively having ohmic contact characteristics with the first and second conductivity type semiconductor layers 121 and 123. For example, the first and second electrodes 124a and 124b may be formed by a process of depositing or sputtering at least one of Au, Ag, Cu, Zn, Al, In, Ti, Si, Ge, Sn, Mg, Ta, Cr, W, Ru, Rh, Ir, Ni, Pd, Pt, and a transparent conductive oxide (TCO). The first and second electrodes 124a and 124b may be disposed on the surface of the package body 110 on which the light emitting diode chip 120 is mounted.

The wavelength conversion layer 130 may be disposed on the upper surface of the light emitting diode chip 120. The wavelength conversion layer 130 may be a sheet type conversion layer having a substantially constant thickness. Further, the wavelength conversion layer 130 may be a film in which a fluorescent material, for example, is dispersed in a half-cured (e.g., B-stage) material, in a half-cured state at room temperature and undergoes a phase transition to be flowable when heated.

More specifically, the half-cured material may be a B-stage silicone. Here, the wavelength conversion layer 130 may be formed of a single layer or a plurality of layers. When the wavelength conversion layer 130 is formed of the plurality of layers, each layer may include a different kind of fluorescent material.

The wavelength conversion layer 130 maybe formed by mixing fluorescent particles with a half-cured resin. For example, the wavelength conversion layer 130 may be a half-cured (e.g., B-stage) composite material in which a fluorescent material is mixed with a polymer binder formed of a resin, a curing agent, and a curing catalyst.

As the fluorescent material, a garnet-group fluorescent material (e.g., YAG, TAG, and LuAG), a silicate-group fluorescent material, a nitride-based fluorescent material, a sulfide-based fluorescent material, and an oxide-based fluorescent material may be used. The fluorescent material may be composed of a single kind of material or a plurality of kinds of materials mixed in a predetermined ratio. In an exemplary embodiment of the present inventive concept, the fluorescent material may include at least a red fluorescent material.

The resin used in the wavelength conversion layer 130 may be a resin satisfying requirements for high adhesion, high light transmittance, high thermal stability, high optical refractive index, moisture resistance, and the like, that is, for example, an epoxy-group material or silicone, an inorganic-based polymer.

In order to ensure a high adhesive property, a silane-based material, for example, may be used as an additive for improving adhesion.

FIG. 2 schematically illustrates a structure of the wavelength conversion layer 130. The wavelength conversion layer 130 may be formed of a single layer as illustrated in FIG. 2, or a plurality of stacked layers as described above. When the wavelength conversion layer 130 is formed of the plurality of layers, each layer of resin material may have different properties.

For example, a resin material forming an upper layer of the wavelength conversion layer 130 may have a higher strength than a resin material forming a lower layer thereof in order for the wavelength conversion layer 130 to maintain a stable shape. In addition, a resin material forming a layer in contact with the light emitting diode chip 120 may have a higher adhesion than the resin material forming the upper layer in order to facilitate easy adhesion to the light emitting diode chip 120. In addition, one of the plurality of layers may be formed of a transparent layer including no fluorescent material.

The encapsulating portion 140 may be arranged to surround the light emitting diode chip 120 and the wavelength conversion layer 130. The encapsulating portion 140 may encapsulate the light emitting diode chip 120 and the wavelength conversion layer 130 to protect the light emitting diode chip 120 and the wavelength conversion layer 130 from moisture and heat. In addition, the encapsulating portion 140 may control the distribution of light emitted by the light emitting diode chip 120 by adjusting the shape of a surface.

The encapsulating portion 140 may be formed of a light transmitting material, more specifically, an insulating resin having light transmittance, such as silicone, a modified silicone, epoxy, urethane, oxetane, acrylic, polycarbonate, polyimide, and a composition consisting of a combination thereof. However, the encapsulating portion 140 is not limited thereto, and an inorganic material having high light resistance, such as glass and silica gel, may be used.

As illustrated in FIG. 2, an upper surface 141 of the encapsulating portion 140 may be formed to have a flat surface substantially parallel to a surface of the wavelength conversion layer 130, and a plurality of side slope sections 142 inclined toward the upper surface 141 may be formed on side surfaces of the encapsulating portion 140. The side slope section 142 may have a surface inclined toward the upper surface 141, and have a predetermined angle (90°−θ₁) from an upper surface of the package body 110 toward the upper surface 141 of the encapsulating portion 140.

Here, θ₁ may be an angle of 30° to 70°. Accordingly, when the side slope section 142 is not formed, an internal angle (θ₂) of an edge E1 at which a side surface and an upper surface of an encapsulating portion meet, may be about 90°, however, according to an exemplary embodiment of the present inventive concept, an internal angle (θ₃) of an edge E2 at which that the side slope section 142 and the upper surface 141 of the encapsulating portion 140 meet, may be an obtuse angle greater than 90°.

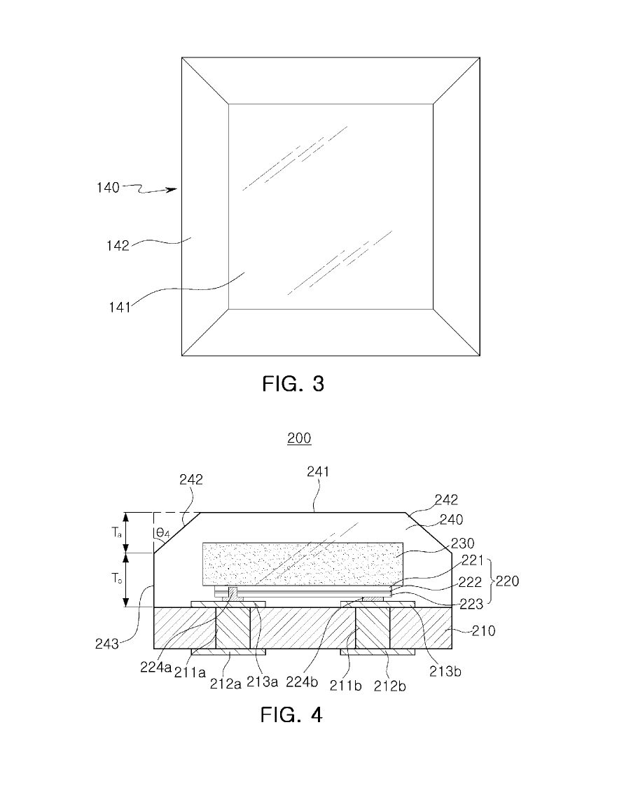

Here, the side slope sections 142 may have the same angle from edges of the upper surface of the package body 110 toward the upper surface 141 of the encapsulating portion 140. Accordingly, when viewed from the upper surface 141, the side slope sections 142 may have the same shape as illustrated in FIG. 3, but is not limited thereto. That is, two facing side slope sections 142 among the plurality of the side slope sections 142 may be formed to have the same shape.

Shapes employed in the side slope section 142 according to an exemplary embodiment of the present inventive concept will be described in more detail. The side slope section 142 may connect the upper surface 141 of the encapsulating portion 140 to the edge of the upper surface of the package body 110, and may be formed at a position corresponding to each side surface of the light emitting diode chip 120.

The side slope section 142 may be formed in such a manner that one side slope section 142 is formed on each side surface of the light emitting diode chip 120, but is not limited thereto. The side slope section 142 may be formed in such a manner that an edge at which the side slope sections 142 meet each other is rounded to have a connected side slope section 142 (not shown). Further, according to another exemplary embodiment of the present inventive concept, to be described later, more side slop sections may be formed on each edge.

Compared to shapes of existing encapsulating portions in the art, the shape of the encapsulating portion 140 according to exemplary embodiments of the present inventive concept may increase color quality and the light emission amount in the light emitting diode package 100, which will be described later.

Next, a light emitting diode package 200 according to a second exemplary embodiment of the present inventive concept is described. FIG. 4 is a cross-sectional view of the light emitting diode package 200 according to the second exemplary embodiment of the present inventive concept.

In the second exemplary embodiment of the present inventive concept, when compared to the first exemplary embodiment of the present inventive concept, there is a difference in that a side slope section 242 may be formed to extend from a flat surface formed on the same plane as, e.g., coplanar with, a side surface of the package body 210. Since other components are the same as those of the first exemplary embodiment of the present inventive concept, different components from those of the first exemplary embodiment will be mainly described for simplicity of description.

As illustrated in FIG. 4, the light emitting diode package 200 according to the second exemplary embodiment of the present inventive concept may include, like the first exemplary embodiment of the present inventive concept, first and second through electrodes 211a and 211b formed in a thickness direction, a package body 210 having first and second electrode structures 213a and 213b and first and second lower electrodes 212a and 212b respectively disposed on both ends of the first and second through electrodes 211a and 211b, and first and second electrode 224a and 224b mounted on a surface of the first and second electrode structures 213a and 213b. In addition, the light emitting diode package 200 according to the second of the present disclosure may include a light emitting diode chip 220 having first and second conductivity type semiconductor layers 221 and 223 and an active layer 222, a wavelength conversion layer 230 disposed on an upper surface of the light emitting diode chip 220, and an encapsulating portion 240 configured to surround the light emitting diode chip 220 and the wavelength conversion layer 230.

Although the side slope section 242 is formed on the encapsulating portion 240 in the same manner as that of the first exemplary embodiment of the present inventive concept, there is a difference in that the side slope section 242 may be formed to extend from a flat portion 243 formed on the same plane as, e.g., coplanar with, a side surface of the package body 210.

Due to the difference, a side slope section 242 according to an exemplary embodiment of the present inventive concept may be formed to be spaced apart from the upper surface of the package body 210 by a predetermined distance. By forming the side slope section 242 to be spaced apart from the upper surface of the package body 210, the amount of the encapsulating portion 240 to be removed for forming the side slope section 242 can be reduced, as compared to the first exemplary embodiment of the present inventive concept. In addition, the wavelength conversion layer 230 can be prevented from being exposed on the side slope section 242 when the side slope section 242 is formed at a gentle angle due to errors in a manufacturing process. In addition, since an internal angle (90°−θ₄) of the side slope section 242 may be formed at a smaller angle, the side slope section 242 and an upper surface 241 of the encapsulating portion 240 may form a greater obtuse angle.

Here, in order for the side slope section 242 to be spaced apart from the upper surface of the package body 210 by at least 100 μm, the height T_{b} of the flat portion 243 may be about 100 μm or more. In addition, relative to a direction perpendicular to the package body 210 (e.g., perpendicular to the upper surface of the package body 210), the height Tₐ of the side slope section 242 may be equal to 50% or more of the height T_{b} of the flat portion 243 in order to obtain both effects of advantages of the side slope section 242 and advantages in the manufacturing process.

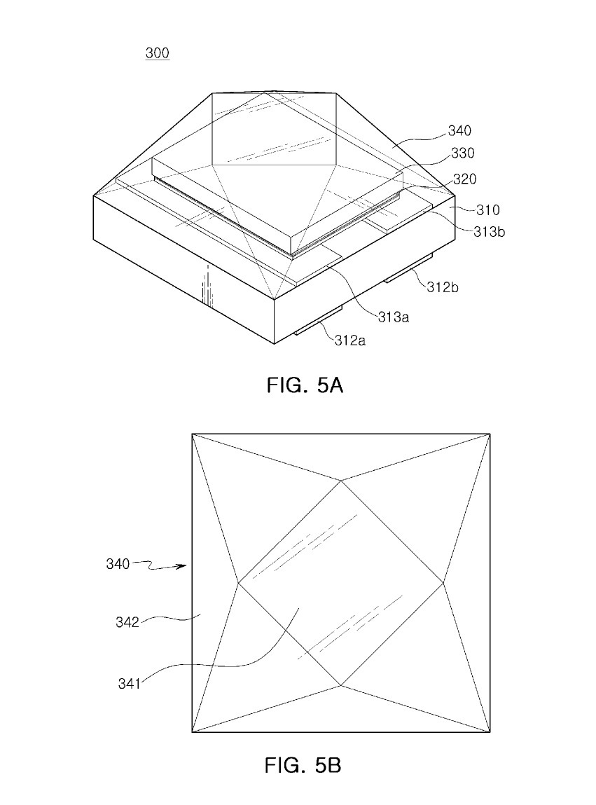

Next, a light emitting diode package 300 according to another exemplary embodiment of the present inventive concept will be described. FIG. 5A is a perspective view of a light emitting diode package according to a third exemplary embodiment of the present inventive concept, and FIG. 5B is a plan view of the light emitting diode package of FIG. 5A.

In the third exemplary embodiment of the present inventive concept, when compared to the first exemplary embodiment of the present inventive concept, there is a difference in that side slope sections 342 of an encapsulating portion 340 may be formed of a greater number of flat surfaces than a number of flat surfaces of the side slope sections 142. Since other components are the same as those of the first exemplary embodiment of the present inventive concept, different components from the first exemplary embodiment of the present inventive concept will be mainly described for simplicity of description.

As illustrated in FIG. 5A, the light emitting diode package 300 according to the third exemplary embodiment of the present inventive concept includes, like the first exemplary embodiment of the present inventive concept, a package body 310 having first and second electrode structures 313a and 313b and first and second lower electrodes 312a and 312b disposed on both ends thereof, a light emitting diode chip 320 mounted on the first and second electrode structures 313a and 313b, a wavelength conversion layer 330 disposed on an upper surface of the light emitting diode chip 320, and an encapsulating portion 340 configured to surround the light emitting diode chip 320 and the wavelength conversion layer 330.

Compared to the above-described first exemplary embodiment of the present inventive concept in which four side slope sections 142 are formed in the encapsulating portion 140 as illustrated in FIG. 3, eight side slope sections 342 may be formed in the encapsulating portion 340 in the third exemplary embodiment of the present inventive concept as illustrated in FIG. 5B. Likewise, since the side slope sections 342 are formed to have a greater number of flat surfaces than a number of flat surfaces of the side slope sections 142 (see FIG. 3), an edge at which the upper surface 341 and the side slope section 342 of the encapsulating portion 340 meet each other may have a greater obtuse angle than an edge at which the upper surface 141 and the side slope section 142 of the encapsulating portion 140 meet each other (see FIG. 3).

Next, an effect of improving color quality of a light emitting diode package will be described.

Generally, an encapsulating portion encapsulating a light emitting diode chip in a wafer level package may have an edge having an internal angle close to a right angle (e.g., with respect to an upper surface of the encapsulating portion) on an upper surface thereof. This is because the light emitting diode chip may be mounted on a mounting board, encapsulated, and then separated into individual light emitting diode packages using a blade having a blade surface perpendicular to the mounting board. The encapsulating portion of this light emitting diode package may have an internal angle θ₂ close to a right angle, like the edge corresponding to E₁ of FIG. 2, and when a white light is incident to the edge, red-green-blue (RGB) light, configuring white light, may be differently refracted depending on respective wavelengths of the RGB light.

Among the light refracted depending on the wavelength, light refracted at a greater angle than a critical angle is not emitted to the outside but reflected back to the inside, i.e., a total internal reflection occurs. A red light having a relatively long wavelength is less refracted as compared to light having other wavelengths, and thus has a relatively high probability of being reflected to the outside. For the same reason, light passing through an edge of the encapsulating portion is predominantly emitted as red light. Such red light may form a red band at a portion corresponding to an angle of about 75° with respect to a light irradiation surface, as illustrated in FIG. 12. Accordingly, color uniformity is poor, and light having low color quality may be irradiated.

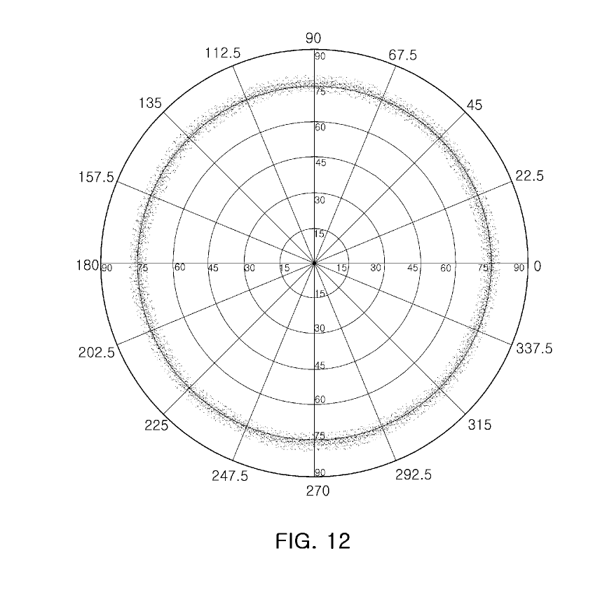

In more detail, as illustrated in FIG. 11, white light which meets a side surface 142′ having an internal angle θ₂ close to a right angle may be emitted to the outside or total internally reflected to the inside depending on a location of the side surface 142′. When optical paths of the white light passing through the side surface 142′ were measured, the optical paths were classified into three types: light passing through a zone D₁, light passing through a zone D₂, and light passing through a zone D₃. The light passing through the zone D₁ was refracted regardless of the wavelength to be emitted to the outside and the light passing through the zone D₂ was total internally reflected to the inside regardless of the wavelength, but the light passing through the zone D₃ was refracted or total internally reflected depending on the wavelength after being total internally reflected from the side surface 142′.

Among these, the light passing through the zones D₁ and D₂ is refracted or total internally reflected regardless of the wavelength, and thus does not form the red band on the light irradiation surface. However, in the light passing through the zone D₃, short wavelength light may not be emitted to the outside since such short wavelength light is total internally reflected and then total internally reflected again. However, long wavelength light such as red light may forma red band in a portion corresponding to an angle of about 75° with respect to the light irradiation surface since the long wavelength light is total internally reflected and then refracted to be emitted to the outside.

According to an exemplary embodiment of the present inventive concept, since a side slope section 142 may be formed on a zone including the zone D₃ as illustrated in FIG. 2, an edge of the upper surface of the encapsulating portion 140 may have an obtuse internal angle θ₃. The edge having the obtuse angle may reduce total reflection of light having a relatively short wavelength to irradiate the light irradiation surface with light having various wavelengths. Accordingly, color uniformity is improved and thus color quality is improved. In particular, these improvements are remarkable when the side slope section 142 forms an angle of 30° to 70° (e.g., θ₁: 20° to 60°) with respect to an upper surface of the package body 110. More specifically, when the side slope section 142 forms an angle of 30° to 60° (e.g., θ₁: 30° to 60°) with respect to the upper surface of the package body 110, the color quality may be further improved.

Next, an effect of increasing the light emission amount of the light emitting diode package will be described.

As described above, normally in wafer-level packages, since an encapsulating portion encapsulating a light emitting diode chip has an edge having an internal angle close to a right angle (with respect to an upper surface of the encapsulation portion) on an upper surface of the encapsulating portion, a side surface of the encapsulating portion may form a surface almost perpendicular to the upper surface of the encapsulation portion.

When described with reference to FIG. 11, as described above, light meeting the side surface 142′ having the internal angle θ₂ close to a right angle may be classified into three types according to the location of the side surface 142′. Light passing through the zone D₁ is refracted regardless of the wavelength to be emitted to the outside and light passing through a zone D₂ is total internally reflected regardless of the wavelength, but light passing through a zone D₃ is refracted or total internally reflected depending on the wavelength after being total internally reflected.

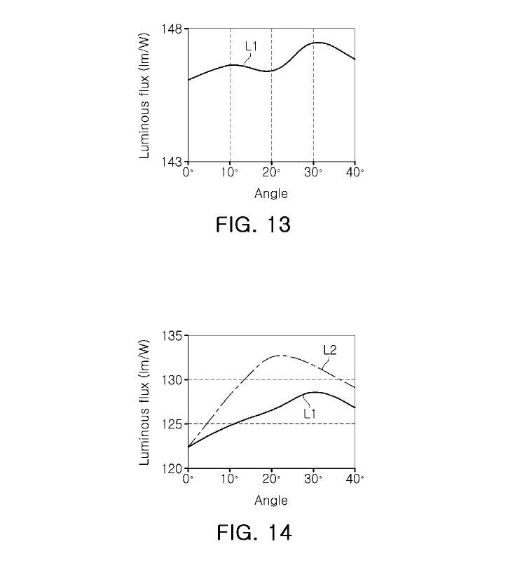

Accordingly, since the light passing through the zone D₂ is total internally reflected to the inside, an external light extraction efficiency may be decreased. When the total reflection is suppressed by forming a side slope section on an area including the zone D₂, the external light extraction efficiency may be improved to obtain an effect of increasing the amount of light emitted by light emitting diode package. FIG. 13 is a diagram illustrating changes in a light emission amount according to the angle of a side slope section when the side slope section is formed at the zone D₂ and the zone D₃ except the zone D₁. This is the casein which the side slope section 242 is formed to extend from a flat surface formed on the same plane as, e.g., coplanar with, the side surface of the package body 210 as shown in FIG. 4.

Line L₁ represents the light emission amount measured according the change of θ₁ when the sum of thicknesses of the zone D₂ and the zone D₃ is about 150 μm. The light emission amount increases compared to the case in which the side slope section is not formed (θ₁: 0°). In particular, this effect is remarkable when the side slope section 242 forms an angle of 45° to 75° with respect to the upper surface of the package body 210 (θ₁: 15° to 45°). More specifically, when the side slope section 242 forms an angle of 60° to 70° with respect to the upper surface of the package body 21 (θ₁: 20° to 30°), the light emission amount may increase.

In addition, the light passing through the zone D₁ is refracted to be emitted to the outside, but does not provide effective light to the light irradiation surface since it propagates in a side direction. Accordingly, when the side slope section is formed at an area including the zone D₁, since the propagation direction of the refracted light is directed to the light irradiation surface, the amount of light radiated on the light irradiation surface may increase. FIG. 14 is a diagram illustrating changes of the light emission amount according to the angle of a side slope section when the side slope section is formed at the zone D₁, the zone D₂, and the zone D₃. As described with reference to FIG. 2, the side slope section 142 may be formed to have a predetermined angle (90°−θ₁) from the edge of the upper surface of the package body 110 toward the upper surface 141 of the encapsulating portion 140.

Referring to FIG. 14, the light emission amount represented by Line L₂ increases compared to the case in which the side slope section is not formed (θ₁: 0°). When compared to a front light measured in the above-described L₁ (see FIG. 13), the amount of light radiated to the light irradiation surface significantly increases. Accordingly, among the light emitted by the light emitting diode package, a side light decreases and a front light increases.

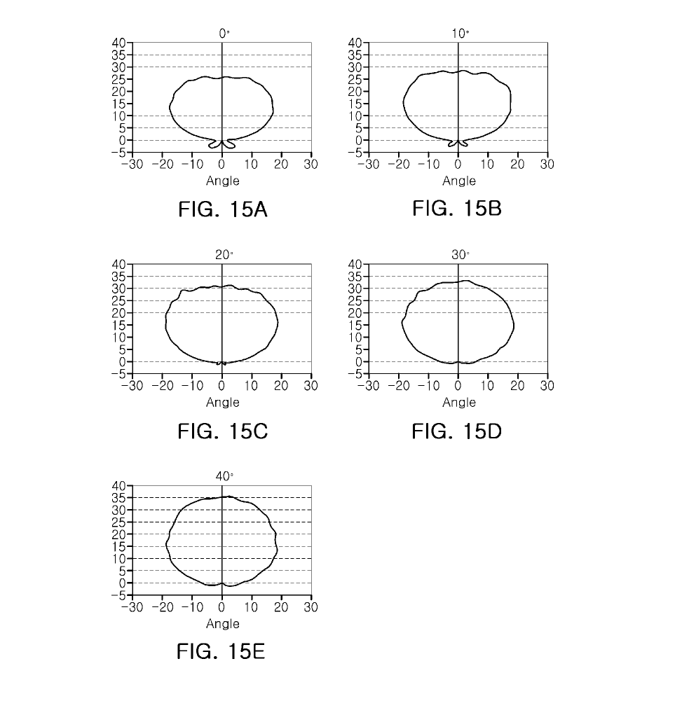

FIGS. 15A to 15E are a diagram illustrating a distribution of light of L₂ according to the angle of the side slope section 142, wherein FIG. 15A illustrates a case in which a side slope section is not formed (θ₁=0°), and FIGS. 15B to 15E respectively illustrate cases in which the angles θ₁ of the side slope sections are 10°, 20°, 30°, and 40°. As shown in FIG. 15A, the amount of light radiated to a front surface, that is, the luminous intensity of light irradiated to the light irradiation surface is about 25.5 cd. However, in FIG. 15E, the luminous intensity of light radiated to a front surface significantly increased to about 34.9 cd.

In particular, these effects are remarkable when the side slope section 142 forms an angle of 45° to 75° with respect to the upper surface of the package body 110 (θ₁: 15° to 45°). More specifically, the light emission amount increases when the side slope section 142 forms an angle of 60° to 70° with respect to the upper surface of the package body 110 (θ₁: 20° to 30°).

The side slope section 142 may be effective regardless of sizes of the light emitting diode chip 120, the wavelength conversion layer 130, and the encapsulating portion 140.

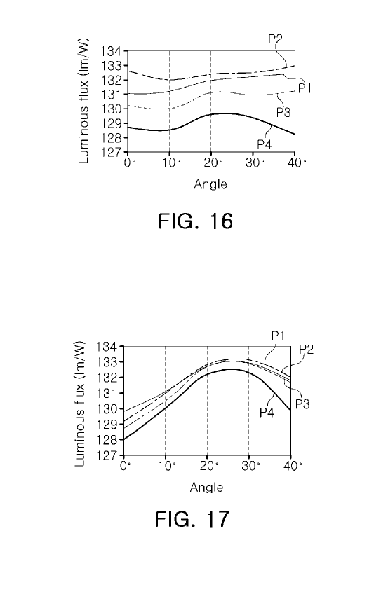

The relationship between the size of the wavelength conversion layer 130 and the light emission amount will be described with reference to FIGS. 16 and 17.

FIGS. 16 and 17 are diagrams illustrating that the change of the amount of light according to the angle of the side slope section 142 is irrelevant to the size of the wavelength conversion layer 130.

P₁, P₂, P₃, and P₄ respectively represents changes of the light emission amount according to the angle of the light emitting diode package including the wavelength conversion layer 130 having the sizes of 0.91 mm×0.91 mm×0.07 mm (length×width×height), 0.96 mm×0.96 mm×0.07 mm (length×width×height), 0.86 mm×0.86 mm×0.07 mm (length×width×height), and 0.81 mm×0.81 mm×0.07 mm (length×width×height), when the size of encapsulating portion 140 is about 1.05 mm×1.25 mm×0.2 mm (length×width×height).

Although the light emission amount varies depending on the size of the wavelength conversion layer 130, the increase of the light emission amount consistently occur when the side slope section 142 is formed to have an angle of 60° to 70 with respect to the upper surface of the package body 110° (θ₁: 20° to 30°).

FIG. 17 is a diagram illustrating the amount of light irradiated to the light irradiation surface, measured under the same conditions as in FIG. 16. Although the light emission amount varies depending on the size of the wavelength conversion layer 130 just like in FIG. 16, the effect in which the light emission amount of light irradiated to the light irradiation surface increases consistently occurs when the side slope section 142 is formed to have an angle of 60° to 70° with respect to the upper surface of the package body 110 (θ₁: 20° to 30°).

In addition, even when the sizes of the light emitting diode chip 120 and the encapsulating portion 140 are changed, although the light emission amount varies depending on the sizes of the light emitting diode chip 120 and the encapsulating portion 140, increases in the light emission amount consistently occur when the side slope section 142 is formed to have an angle of 60° to 70° with respect to the upper surface of the package body 110 (θ₁: 20° to 30°).

Accordingly, since the effect of the side slope section 142 occurs regardless of the sizes of the light emitting diode chip 120, the wavelength conversion layer 130, and the encapsulating portion 140, the light emission amount of various sizes of light emitting diode packages may be controlled by adjusting the side slope section 142.

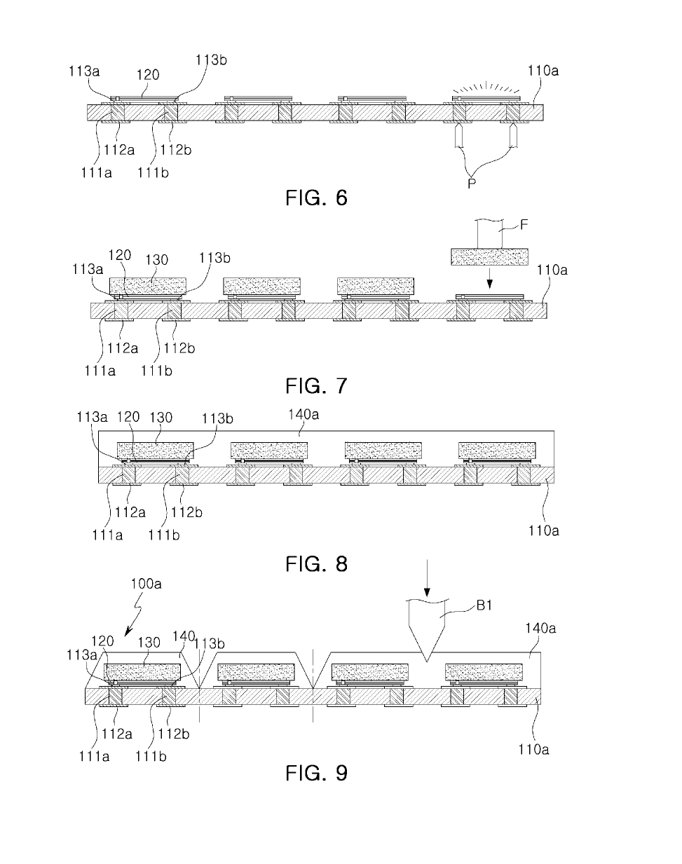

Next, a method of fabricating the light emitting diode package 100 illustrated in FIG. 1 according to an exemplary embodiment of the present inventive concept will be described with reference to FIGS. 6 to 10.

First, as illustrated in FIG. 6, a light emitting diode chip 120 may be mounted on first and second electrode structures 113a and 113b of a package body 110a, and color properties of the light emitting diode chip 120 may be measured by applying power to the light emitting diode chip 120. The measurement of the color properties may be performed by applying power to the light emitting diode chip 120 using a probe P and analyzing emitted light. The color properties may be at least one of a wavelength, power and a full width at half maximum (FWHM), and color coordinates of the light emitted by the light emitting diode chip 120.

Next, as illustrated in FIG. 7, based on the measured color property, a sheet-type wavelength conversion layer 130 may be disposed on the light emitting diode chip 120 using an adsorber F so that the light emitted by the light emitting diode chip 120 has a target color property. The amount of the wavelength conversion layer 130 may be determined by quantifying a ratio of change of the color property (e.g., a color property changing ratio)of the light emitting diode chip 120 to a unit quantity of the wavelength conversion layer 130 and calculating a required wavelength conversion layer based on the color property changing ratio.

Next, as illustrated in FIG. 8, an encapsulating portion 140a may be formed to cover the light emitting diode chip 120 and the wavelength conversion layer 130.

Next, as illustrated in FIG. 9, an encapsulating portion 140 may be formed by cutting the encapsulating portion 140a into individual light emitting diode packages 100a using a blade B1 having a V-shaped cross-section.

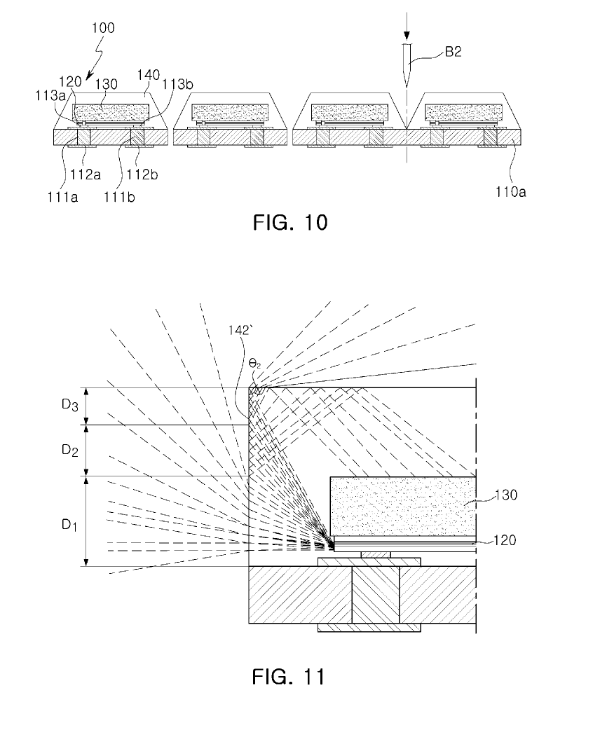

Next, as illustrated in FIG. 10, each light emitting diode package 100 may be formed by cutting the package body 110a using a blade B2 having a narrow cross-section (e.g., narrower than a cross-section of the blade B1).

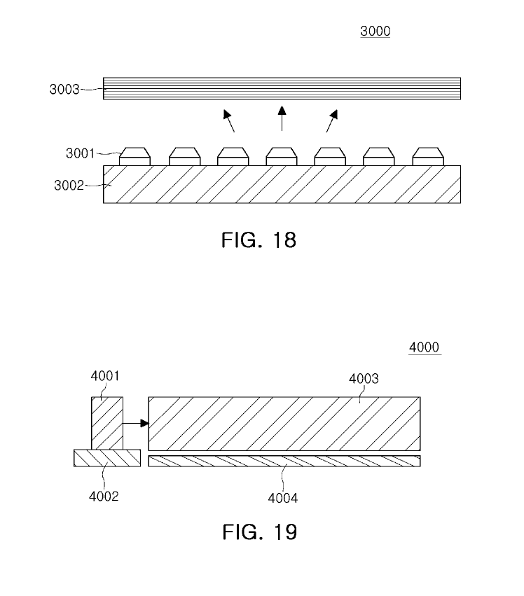

FIGS. 18 and 19 illustrate examples in which a light emitting diode package according to exemplary embodiments of the present inventive concept is applied to backlight units.

Referring to FIG. 18, a backlight unit 3000 may include a light source 3001 mounted on a substrate 3002, and one or more optical sheet 3003 disposed on the light source 3001. The light source 3001 may use a light emitting diode package having the same structure as or similar structure to the light emitting diode package described with reference to FIGS. 1, 4, and 5A, or alight diode chip directly mounted on the substrate 3002 (so called, a chip-on-board (COB) type package).

The light source 3001 in the backlight unit 3000 illustrated in FIG. 18 may emit light toward a top surface where a liquid crystal display (LCD) is disposed. On the contrary, in another backlight unit 4000 illustrated in FIG. 19, a light source 4001 mounted on a substrate 4002 may emit light in a lateral direction, and the emitted light may be incident to a light guide plate 4003 and converted to the form of surface light. Light passing through the light guide plate 4003 may be emitted upwardly, and a reflective layer 4004 may be disposed on a bottom surface of the light guide plate 4003 to improve light extraction efficiency.

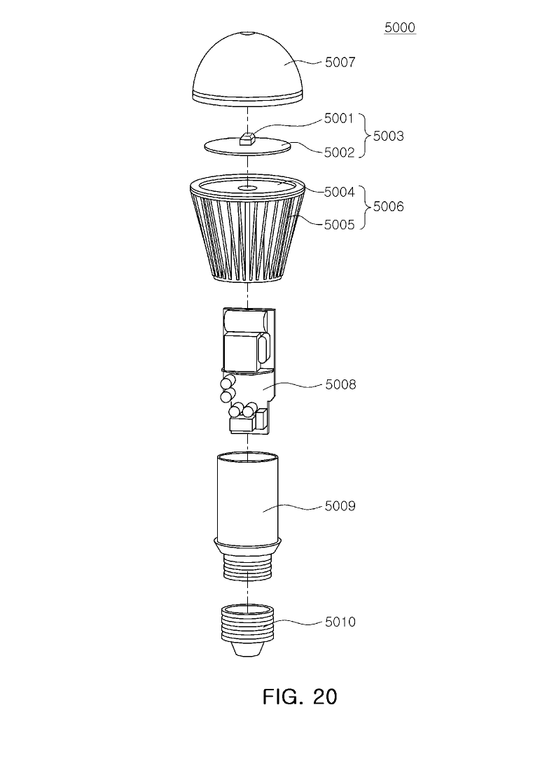

FIG. 20 illustrates an example in which a light emitting diode package according to exemplary embodiments of the present inventive concept is applied to an illumination apparatus.

Referring to an exploded perspective view of FIG. 20, an illumination apparatus 5000 is illustrated as a bulb-type lamp for example, and includes a light emitting module 5003, a driving unit 5008, and an external connection portion 5010.

In addition, external structures, such as external and internal housings 5006 and 5009 and a cover 5007, may be further included. The light emitting module 5003 may include a light emitting diode package 5001 having the same structure as or similar structure to the light emitting diode package described with reference to FIGS. 1, 4, and 5A, and a circuit board 5002 with the light emitting diode package 5001 mounted thereon. In an exemplary embodiment of the present inventive concept, a single light emitting diode package 5001 is mounted on the circuit board 5002, but a plurality of light emitting diode packages 5001 may be mounted as needed.

The external housing 5006 may function as a heat dissipation unit, and include a heat dissipation plate 5004 in direct contact with the light emitting module 5003 to enhance a heat dissipation effect, and a heat radiation fin 5005 surrounding a side surface of the illumination apparatus 5000. The cover 5007 may be installed on the light emitting module 5003, and have a convex lens shape. The driving unit 5008 may be installed in the internal housing 5009 and connected to the external connection portion 5010, such as a socket structure, to receive power from an external power source. In addition, the driving unit 5008 may convert the power to an appropriate current source capable of driving the light emitting diode package 5001 of the light-emitting module 5003. For example, the driving unit 5008 may be configured as an AC-DC converter, a rectifying circuit component, or the like.

In addition, although not illustrated, the illumination apparatus 5000 may further include a communications module.

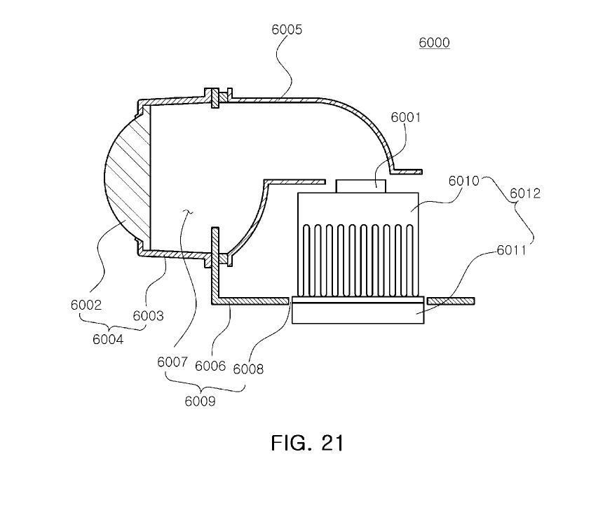

FIG. 21 illustrates an example in which a light emitting diode package according to exemplary embodiments of the present inventive concept is applied to a headlamp.

Referring to FIG. 21, a headlamp 6000 used as a vehicle lamp, or the like, may include a light source 6001, a reflective unit 6005, and a lens cover unit 6004. The lens cover unit 6004 may include a hollow-type guide 6003 and a lens 6002. The light source 6001 may include at least one of the light emitting diode packages described with reference to FIGS. 1, 4, and 5A. In addition, the headlamp 6000 may further include a heat dissipation unit 6012 dissipating heat generated by the light source 6001 outwardly. In order to effectively dissipate heat, the heat dissipation unit 6012 may include a heat sink 6010 and a cooling fan 6011. In addition, the headlamp 6000 may further include a housing 6009 fixedly supporting the heat dissipation unit 6012 and the reflective unit 6005, and the housing 6009 may have a body unit 6006 and a central hole 6008 formed in one surface 6006 thereof, to which the heat dissipation unit 6012 is coupledly installed. Further, the housing 6009 may have a front hole 6007 formed on the other surface integrally connected to the one surface 6006 and bent in a right angle direction. The reflective unit 6005 may be fixed to the housing 6009 so that light reflected by the reflective unit 6005 passes through the front hole 6007 to be emitted outwardly.

The light emitting diode package according to exemplary embodiments of the present inventive concept may have improved color quality and an increased light emission amount.

While exemplary embodiments have been shown and described above, it will be apparent to those skilled in the art that modifications and variations could be made without departing from the spirit and scope of the present disclosure as defined by the appended claims.

What is claimed is:

1. A light emitting diode package, comprising:
a package body including first and second electrode structures;
a light emitting diode chip, including a surface on which first and second electrodes are disposed, disposed on the first and second electrode structures of the package body;
a sheet-type wavelength conversion layer having a substantially constant thickness disposed on an upper surface of the light emitting diode chip; and
an encapsulating portion disposed to surround the light emitting diode chip and the wavelength conversion layer, wherein:
the encapsulating portion has an upper surface substantially parallel to the wavelength conversion layer, and
side surfaces of the encapsulating portion have a plurality of side slope sections inclined toward the upper surface of the encapsulating portion.

2. The light emitting diode package of claim 1, wherein the plurality of side slope sections extend from edges of an upper surface of the package body toward the upper surface of the encapsulating portion at a angle.

3. The light emitting diode package of claim 2, wherein the plurality of side slope sections extend from edges of the upper surface of the package body at an identical angle.

4. The light emitting diode package of claim 1, wherein the plurality of side slope sections include flat surfaces.

5. The light emitting diode package of claim 1, wherein each of the plurality of side slope sections extends from a flat portion coplanar with a side surface of the package body.

6. The light emitting diode package of claim 5, wherein the flat portion has a thickness of at least 100 μm.

7. The light emitting diode package of claim 5, wherein heights of the plurality of side slope sections are greater than or equal to 50% of a height of the flat portion in a direction perpendicular to an upper surface of the package body.

8. The light emitting diode package of claim 1, wherein the plurality of side slope sections correspond to edges of the upper surface of the light emitting diode chip.

9. The light emitting diode package of claim 2, wherein the plurality of side slope sections have an angle of 60° to 70° with respect to the upper surface of the package body.

10. The light emitting diode package of claim 1, wherein the encapsulating portion includes a material selected from the group consisting of silicone, a modified silicone, epoxy, urethane, oxetane, acrylic, polycarbonate, polyimide, and a combination thereof.

11. The light emitting diode package of claim 1, wherein the wavelength conversion layer is a mixture of a half-cured material and a fluorescent material.

12. The light emitting diode package of claim 11, wherein the fluorescent material includes at least a red fluorescent material.

13. The light emitting diode package of claim 1, wherein the package body includes a flat surface.

14. The light emitting diode package of claim 13, wherein the first and second electrode structures include first and second through electrodes passing through the package body.

15. A light emitting apparatus, comprising:
a mounting board; and
a light emitting diode package disposed on the mounting board and emitting light when power is applied,
wherein the light emitting diode package comprises:
a package body including first and second electrode structures;
a light emitting diode chip, including a surface on which first and second electrodes are disposed, disposed on the first and second electrode structures of the package body;
a sheet-type wavelength conversion layer having a substantially constant thickness disposed on an upper surface of the light emitting diode chip and; and
an encapsulating portion disposed to surround the light emitting diode chip and the wavelength conversion layer,
wherein the encapsulating portion has an upper surface substantially parallel to the wavelength conversion layer, and a side surface inclined toward the upper surface of the encapsulating portion.

16. A backlight unit, comprising:
a substrate; and
a light source including the light emitting diode package of claim 1, disposed on the substrate and configured to emit light from a top surface of the light source or from a side surface of the light source.

17. An illumination apparatus, comprising:
a light emitting module including the light emitting diode package of claim 1 and a circuit board with the light emitting diode package disposed thereon;
a driving unit configured to drive the light emitting module; and
a heat dissipation plate disposed in direct contact with the light emitting module.

18. A light emitting diode package, comprising:
a package body including first and second electrode structures;
a light emitting diode chip disposed on the first and second electrode structures of the package body;
a sheet-type wavelength conversion layer disposed on an upper surface of the light emitting diode chip; and
an encapsulating portion disposed to surround the light emitting diode chip and the wavelength conversion layer, wherein:
the encapsulating portion has an upper surface parallel to the wavelength conversion layer,
side surfaces of the encapsulating portion have a flat surface coplanar with a side surface of package body, and a plurality of side slope sections extending from the flat surface and inclined toward the upper surface of the encapsulating portion, and
the plurality of side slope sections have a height greater than or equal to a first height in a direction perpendicular to an upper surface of the package body such that when light emitted from the light emitting diode chip is total internally reflected from the flat surface to an inside of the encapsulating portion, the total internally reflected light is not emitted through the upper surface of the encapsulating portion to an outside of the encapsulating portion.

19. The light emitting diode package of claim 18, wherein the plurality of side slope sections have a height greater than or equal to a second height such that the second height is greater than the first height, and light emitted from the light emitting diode chip is not total internally reflected from the flat surface to the inside of the encapsulating portion.

20. The light emitting diode package of claim 19, wherein the plurality of side slope sections have a height greater than or equal to a third height such that the third height is greater than the second height, and light emitted from the light emitting diode chip is total internally reflected and not emitted through the flat surface to the outside of the encapsulating portion.
